(19) United States
(12) Patent Application Publication
(10) Pub. No.: US 2025/0349698 A1
(43) Pub. Date: Nov. 13, 2025

(54) SEMICONDUCTOR PACKAGE

(71) Applicant: Samsung Electronics Co., Ltd., Suwon-si (KR)

(72) Inventors: Minwoo Cho, Suwon-si (KR); Junho Lee, Suwon-si (KR)

(21) Appl. No.: 18/943,105

(22) Filed: Nov. 11, 2024

(30) Foreign Application Priority Data
May 13, 2024 (KR) 10-2024-0062666

(51) Int. Cl. H01L 23/498; H01L 23/00; H01L 23/373; H01L 25/065; H01L 25/18; H05K 1/02; H05K 1/11; H05K 1/18; H10B 80/00

(52) U.S. Cl. CPC H01L 23/49838; H01L 23/3736; H01L 23/49816; H01L 23/49822; H01L 24/08; H01L 24/16; H01L 24/32; H01L 24/73; H01L 25/0655; H01L 25/18; H05K 1/0271; H05K 1/112; H05K 1/181; H01L 2224/08113; H01L 2224/16227; H01L 2224/16237; H01L 2224/73204; H01L 2224/73253; H01L 2924/35; H01L 2924/384; H05K 2201/09409; H05K 2201/09472; H05K 2201/10234; H05K 2201/10522; H05K 2201/10734; H10B 80/00

(57) ABSTRACT

A semiconductor package includes a substrate, at least one chip structure on a first surface of the substrate, connection bumps, an underfill layer that at least partially surrounds the connection bumps and is between the first surface of the substrate and the at least one chip structure, core balls, and conductive bumps on a second surface of the substrate, where respective ones of the core balls and respective ones of the conductive bumps are electrically connected to the respective ones of the lower pads, where each of the core balls includes a core body and a conductive material layer that at least partially surrounds and extends into the core body, and where a width of each of the core balls in a first direction is less than a width of each of the conductive bumps in the first direction.

### CROSS-REFERENCE TO RELATED APPLICATION(S)

This application claims benefit of priority to Korean Patent Application No. 10-2024-0062666 filed on May 13, 2024 in the Korean Intellectual Property Office, the disclosure of which is incorporated herein by reference in its entirety.

### TECHNICAL FIELD

The present disclosure relates to a semiconductor package.

### BACKGROUND

In accordance with the trend for high-performance electronic products, a semiconductor package in which a high-performance semiconductor chip is mounted on a large-area substrate has been developed. An increase in an area of a substrate, an asymmetrical arrangement of chip structures, and an increase in a weight of heat dissipation structures may increase warpage of semiconductor packages, thereby increasing a likelihood of an occurrence of a short circuit in external connection bumps.

### SUMMARY

An aspect of the present disclosure provides a semiconductor package having improved reliability.

According to an aspect of the present disclosure, there is provided a semiconductor package including a substrate that includes upper pads, lower pads, and an interconnection layer electrically connecting respective ones of the upper pads and respective ones of the lower pads to each other, at least one chip structure on a first surface of the substrate, where each of the at least one chip structure includes connection pads, connection bumps electrically connecting respective ones of the connection pads to the respective ones of the upper pads of the substrate, an underfill layer that at least partially surrounds the connection bumps and is between the first surface of the substrate and the at least one chip structure, and core balls and conductive bumps on a second surface of the substrate that is opposite to the first surface of the substrate, where respective ones of the core balls and respective ones of the conductive bumps are electrically connected to the respective ones of the lower pads, where each of the core balls includes a core body and a conductive material layer that at least partially surrounds and extends into the core body, and where a width of each of the core balls in a first direction that is parallel to the second surface of the substrate is less than a width of each of the conductive bumps in the first direction.

According to another aspect of the present disclosure, there is provided a semiconductor package including a substrate that includes lower pads and an interconnection layer electrically connected to the lower pads, at least one chip structure that is on the substrate and is electrically connected to the interconnection layer, and core balls on respective ones of the lower pads of the substrate, where the core balls are electrically connected to the at least one chip structure through the interconnection layer, where each of at least one core ball of the core balls includes a core body and a conductive material layer that at least partially surrounds the core body, where the core body includes an external surface and an internal surface that define a through-hole extending from a first side of the external surface to a second side of the external surface, and where the conductive material layer extends along the external surface and the internal surface of the core body.

According to another aspect of the present disclosure, there is provided a semiconductor package including a substrate that includes lower pads and an interconnection layer electrically connected to the lower pads, at least one chip structure that is on the substrate and is electrically connected to the interconnection layer, and a plurality of external connection bumps respectively on the lower pads, where the plurality of external connection bumps include core balls and conductive bumps, where the core balls include a core body and a conductive material layer that at least partially surrounds a surface of the core body, where a first core ball of the core balls and a second core ball of the core balls are spaced apart from each other by a first distance in a direction that is parallel to a lower surface of the substrate, where the first core ball and a first conductive bump of the conductive bumps are spaced apart from each other by a second distance in the direction, and where the second distance is less than the first distance.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a cross-sectional view of a semiconductor package according to an example embodiment, and FIG. 1B is a lower view taken along line I-I′ of FIG. 1A;

FIG. 2 is a partially enlarged view of region “A” of FIG. 1A, and FIG. 3 is a partially enlarged view of region “B” of FIG. 1A;

FIG. 4 is a partially enlarged view of a semiconductor package according to an example embodiment;

FIG. 5 is a partially enlarged view of a semiconductor package according to an example embodiment;

FIG. 6 is a partially enlarged view of a semiconductor package according to an example embodiment;

FIG. 7 is a partially enlarged view of a semiconductor package according to an example embodiment;

FIG. 8A is a cross-sectional view of a semiconductor package according to an example embodiment, FIG. 8B is a plan view of the semiconductor package in FIG. 8A, and FIG. 8C is a cross-sectional view of a chip structure according to an example embodiment;

FIG. 9 is a cross-sectional view of a semiconductor package according to an example embodiment;

FIG. 10 is a diagram of a use state of a semiconductor package according to an example embodiment; and

FIGS. 11A, 11B, and 11C are diagrams of a process of manufacturing a semiconductor package according to an example embodiment.

### DETAILED DESCRIPTION

Hereinafter, example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually arranged.

In addition, ordinal numbers such as “first,” “second,” “third,” and the like may be used as labels for specific elements, operations, directions, and the like, to distinguish various elements, steps, directions, and the like from one another. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device.

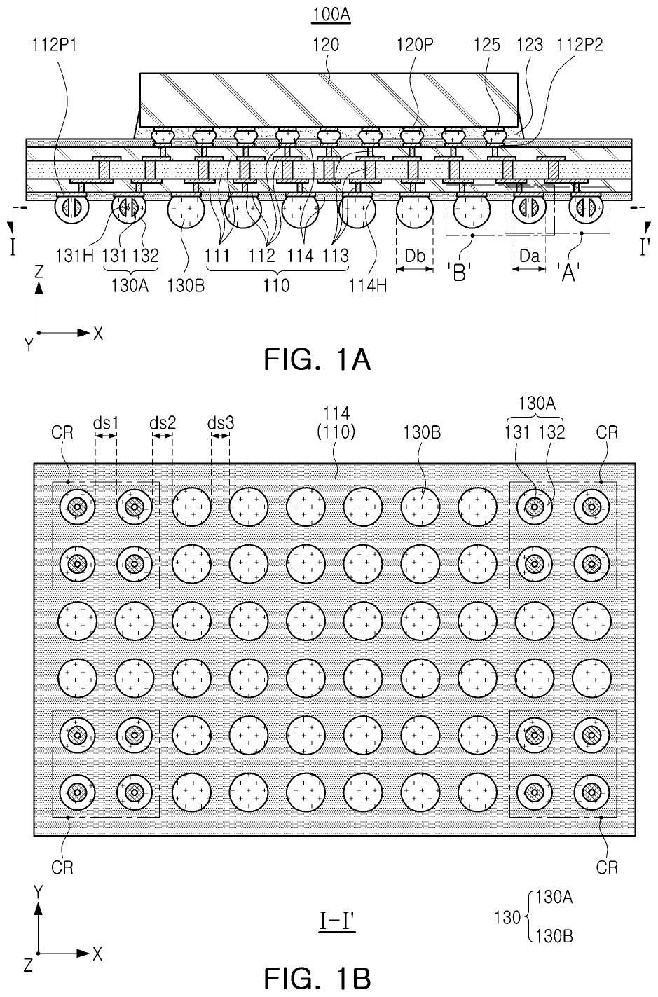

FIG. 1A is a cross-sectional view of a semiconductor package 100A according to an example embodiment, and FIG. 1B is a lower view taken along line I-I′ of FIG. 1A.

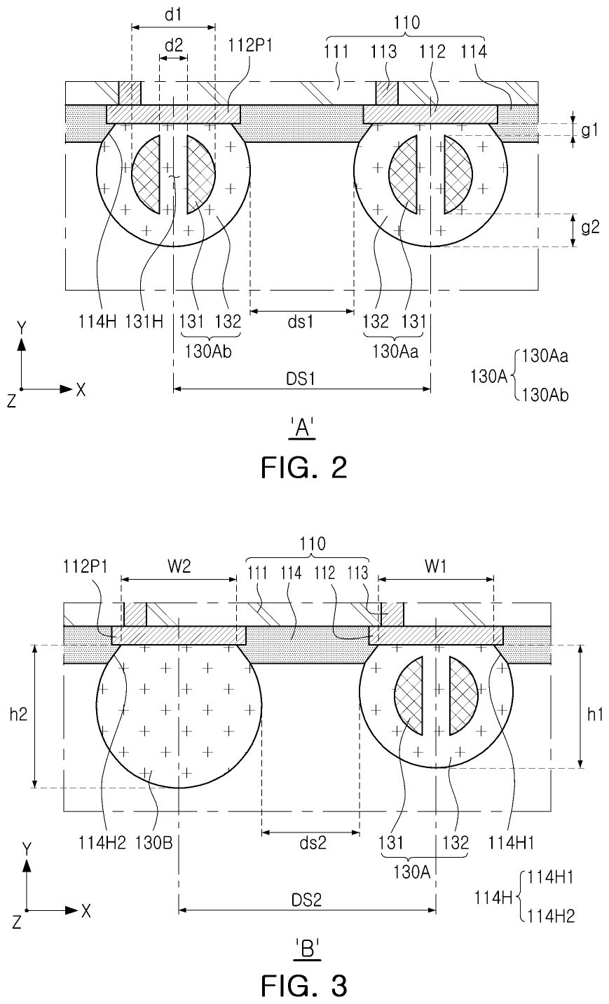

FIG. 2 is a partially enlarged view of region “A” of FIG. 1A, and FIG. 3 is a partially enlarged view of region “B” of FIG. 1A.

First, referring to FIGS. 1A and 1B, the semiconductor package 100A according to an example embodiment may include a substrate 110, at least one chip structure 120, and a plurality of external connection bumps 130.

The substrate 110 is a support substrate on which at least one chip structure 120 is mounted, and may be a package substrate for redistributing a connection pad 120P of the chip structure 120. For example, the substrate 110 may include a printed circuit board (PCB), a ceramic substrate, a glass substrate, a tape interconnection substrate, or the like. In addition, the substrate 110 may be a large-area substrate on which the at least one chip structure 120 is mounted. For example, the substrate 110 may have a planar shape such as a square or rectangle, and a width of the substrate 110 may be greater than or equal to 40 mm, but the present disclosure is not limited thereto.

The substrate 110 may include an insulating layer 111, an interconnection layer 112, and interconnection vias 113. The insulating layer 111 may include an insulating resin electrically and physically protecting the interconnection layer 112, for example, a thermosetting resin such as an epoxy resin, a thermoplastic resin such as polyimide, or a prepreg, an Ajinomoto build-up film (ABF), a frame retardant 4 (FR4) including an inorganic filler and/or a glass fiber (or glass cloth or glass fabric), or a photosensitive resin such as a photoimageable dielectric (PID).

The insulating layer 111 may include a plurality of insulating layers 111 stacked in a vertical direction (e.g., a Z direction). Depending on a process, a boundary between the plurality of insulating layers 111 may be unclear or indistinct. In addition, for ease of description, only a three-layer insulating layers 111 are illustrated in the drawing, but example embodiments of the present disclosure are not limited thereto. For example, a core insulating layer 111, positioned in the center of the plurality of insulating layers 111, may be thicker than insulating layers 111 stacked above and below the plurality of insulating layers 111. The core insulating layer 111 may improve rigidity of a substrate and suppress warpage of the substrate. The core insulating layer 111 may be formed using, for example, a copper clad laminate (CCL), an unclad CCL, a glass substrate, or a ceramic substrate. In some example embodiments, the substrate 110 may not include the core insulating layer 111.

In some example embodiments, the substrate 110 may further include a protective layer 114. The protective layer 114 may cover or overlap an uppermost insulating layer 111 and a lowermost insulating layer 111 in the Z direction, and may protect the interconnection layer 112 from external physical and chemical damage. The protective layer 114 may include an insulating material, and may be formed using, for example, a photo solder resist (PSR). The protective layer 114 may expose at least a portion of each of lower pads 112P1 and upper pads 112P2. The protective layer 114 may have openings 114H exposing at least a portion of each of the lower pads 112P1. A plurality of external connection bumps 130 may be respectively disposed in the openings 114H of the protective layer 114.

The interconnection layer 112 may include, for example, a metal material including copper (Cu), aluminum (Al), silver (Ag), tin (Sn), gold (Au), nickel (Ni), lead (Pb), titanium (Ti), or alloys thereof. The interconnection layer 112 may electrically connect the lower pads 112P1 and the upper pads 112P2 to each other. The interconnection layer 112 may include, for example, a ground pattern, a power pattern, and a signal pattern. The signal pattern may provide a path through which various signals, such as data signals, are transmitted/received. The interconnection layer 112 may include a plurality of interconnection layers 112 disposed in the insulating layer 111. The plurality of interconnection layers 112 may be electrically connected to each other through the interconnection vias 113. The number of layers of the interconnection layer 112 may be determined depending on the number of layers of the insulating layer 111, and the interconnection layers 112 may include more or less layers than those illustrated in the drawings.

The interconnection vias 113 may be connected to the interconnection layer 112. The interconnection vias 113 may electrically connect the interconnection layer 112 to the lower pads 112P1 and the upper pads 112P2. The interconnection vias 113 may include, for example, a metal material including copper (Cu), aluminum (Al), silver (Ag), tin (Sn), gold (Au), nickel (Ni), lead (Pb), titanium (Ti), or alloys thereof. The interconnection vias 113 may be a filled via in which a via hole is filled with or includes a metal material or a conformal via in which a metal material is formed along an internal wall of a via hole. The interconnection vias 113 may be integrated with the interconnection layer 112, but example embodiments of the present disclosure are not limited thereto.

The at least one chip structure 120 may be disposed on the substrate 110, and may include connection pads 120P electrically connected to the interconnection layer 112 of the substrate 110. The connection pads 120P may be electrically connected to the upper pads 112P2 of the substrate 110 through connection bumps 125. The connection bumps 125 may include, for example, tin (Sn) or an alloy including tin (Sn). In some example embodiments, the connection bumps 125 may include a metal pillar in contact with the connection pads 120P, and a solder ball in contact with the upper pads 112P2.

In some example embodiments, an underfill layer 123 may be disposed between the chip structure 120 and the substrate 110. The underfill layer 123 may surround at least a portion of the connection bumps 125, and may be between the substrate 110 and the at least one chip structure 120. The underfill layer 123 may have a capillary underfill (CUF) structure, but the present disclosure is not limited thereto. In some example embodiments, the underfill layer 123 may have a molded underfill (MUF) structure integrated with a molded layer covering or overlapping the chip structure 120.

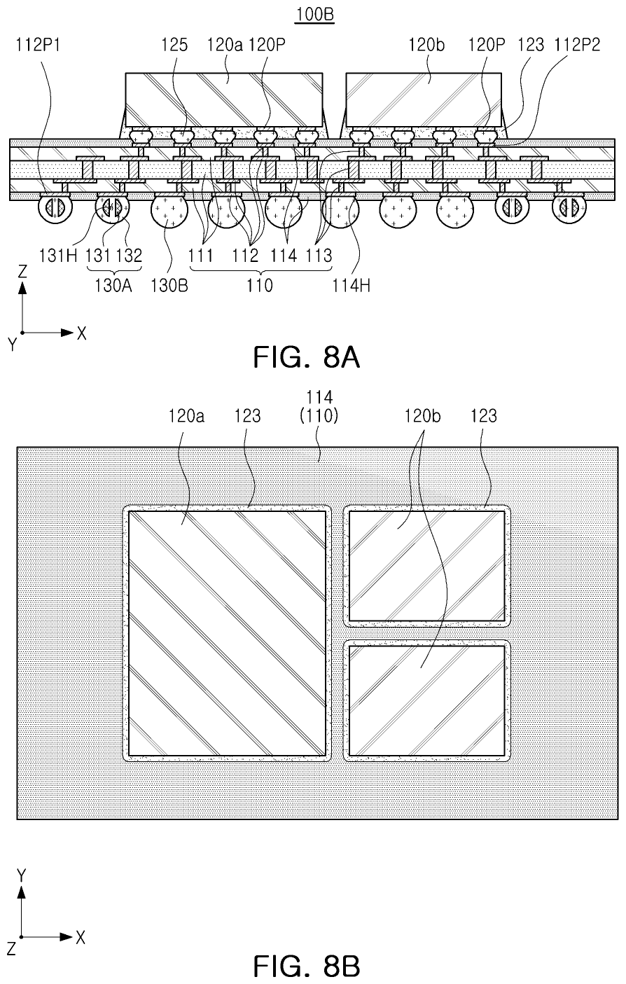

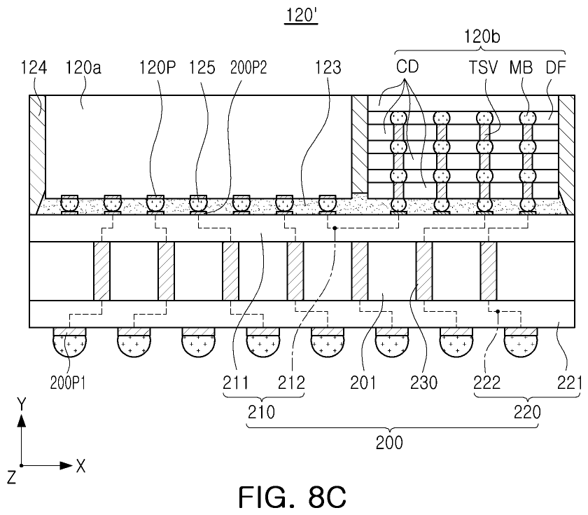

The at least one chip structure 120 may include a semiconductor wafer and an integrated circuit (IC) including a semiconductor element such as silicon or germanium, or a compound semiconductor such as silicon carbide (SiC), gallium arsenide (GaAs), indium arsenide (InAs), or indium phosphide (InP). The chip structure 120 may be a bare semiconductor chip without a bump or an interconnection layer, but the present disclosure is not limited thereto, and may be a packaged-type semiconductor chip. The at least one chip structure 120 may include a logic circuit (“logic chip”) such as a central processing unit (CPU), a graphics processing unit (GPU), a field programmable gate array (FPGA), an application processor (AP), a digital signal processor, a cryptographic processor, a microprocessor, a microcontroller, an analog-to-digital processor, or an application-specific IC (ASIC), or a memory circuit (or “memory chip”) including a volatile memory such as dynamic RAM (DRAM) or static RAM (SRAM), and a non-volatile memory such as PRAM, MRAM, RRAM, or flash memory. In some example embodiments, the at least one chip structure 120 may be a package structure including a plurality of semiconductor chips, which will be described below with reference to FIG. 8C.

The plurality of external connection bumps 130 may electrically connect the semiconductor package 100A to an external device such as a module substrate, a main board, or the like. The plurality of external connection bumps 130 may be disposed on the lower pads 112P1 of the substrate 110, respectively. The plurality of external connection bumps 130 may be electrically connected to the chip structure 120 through the interconnection layer 112 of the substrate 110. For example, the plurality of external connection bumps 130 may have a flip-chip connection structure having a grid array such as a ball grid array. The plurality of external connection bumps 130 may include tin (Sn), indium (In), bismuth (Bi), antimony (Sb), copper (Cu), silver (Ag), zinc (Zn), lead (Pb), and/or alloys thereof (for example, Sn-Ag-Cu). The plurality of external connection bumps 130 may have a spherical or ellipsoid shape.

In an example embodiment, the plurality of external connection bumps 130 may include core balls 130A and conductive bumps 130B. At least some core balls, among the core balls 130A, may have a relatively small size (for example, a width, a height, a volume, or the like), as compared to the conductive bumps 130B. The core balls 130A may include a core body 131 having a through-hole 131H and a conductive material layer 132 filling or in the through-hole 131H. The core body 131 may support the core balls 130A in a vertical direction (Z direction) to prevent the core balls 130A from being excessively pressed, and may reduce a width of each of the core balls 130A in a horizontal direction (X- and/or Y-direction). Accordingly, the core balls 130A may secure a margin between adjacent bumps, thereby preventing or inhibiting the occurrence of a short circuit between the plurality of external connection bumps 130 arranged at a fine or reduced/smaller pitch.

The core body 131 and the conductive material layer 132 may include different metals. The core body 131 may include a first metal, and the conductive material layer 132 may include a second metal having a melting point lower than a melting point of the first metal. For example, the core body 131 may include copper (Cu), and the conductive material layer 132 may include tin (Sn) or an alloy of tin (Sn) (for example, a Sn—Ag—Cu alloy). The conductive bumps 130B may include a material similar to that of the conductive material layer 132 of the core balls 130A, for example, tin (Sn) or an alloy of tin (Sn) (for example, a Sn—Ag—Cu alloy). The conductive material layer 132 may surround at least a portion of the core body 131, and may extend into the core body 131. The conductive material layer 132 may pass through the inside of the core body 131.

At least some core balls 130A, in which a portion of the conductive material layer 132 is filled in the through-hole 131H of the core body 131, may have a width that is reduced in a horizontal direction. For example, a horizontal width (e.g., a width in the X-direction) Da of each of the at least some core balls 130A may be less than a horizontal width Db of each of the conductive bumps 130B. Accordingly, a separation distance between the at least some core balls 130A and adjacent bumps (for example, the core balls 130A and/or the conductive bumps 130B) may be increased. For example, core balls 130A that are adjacent to each other may be spaced apart from each other by a first distance ds1 in the X-direction, and at least one of core balls 130A and at least one of conductive bumps 130B that are adjacent to each other may be spaced apart from each other by a second distance ds2 in the X-direction that is less than the first distance ds1. A third distance ds3 in the X-direction between conductive bumps 130B that are adjacent to each other may be less than the first distance ds1 and the second distance ds2. In an example embodiment, the core balls 130A may be selectively arranged in a region in which a short circuit between the external connection bumps 130 is more likely to occur. For example, the core balls 130A may be disposed on the lower pads 112P1, adjacent to edges of the substrate 110. In plan view, the core balls 130A may be disposed in a corner region CR of the substrate 110. The corner region CR may be defined as a region adjacent to a vertex of the substrate 110 or a region adjacent to the edges of the substrate 110 that meet or intersect each other. However, a region in which the core balls 130A are disposed is not particularly limited, and may be determined in consideration of warpage properties of the substrate 110, the chip structure 120, and the like.

Hereinafter, the core balls 130A and the conductive bumps 130B will be described in more detail with reference to FIGS. 2 and 3.

Referring to FIG. 2, the at least some core balls 130A may include a core body 131 and a conductive material layer 132. The core body 131 may have an external surface and an internal surface defining a through-hole 131H extending from one side of the external surface to the other side of the external surface. The through-hole 131H may entirely pass through or extend into the core body 131. The conductive material layer 132 may integrally extend along the external surface and the internal surface of the core body 131. The conductive material layer 132 may include an external shell portion surrounding the external surface of the core body 131, and a filling portion filling or in the through-hole 131H of the core body 131. The exterior of the core balls 130A, for example, a horizontal width, a height, or the like, may be defined by the external shell portion of the conductive material layer 132. The core body 131 may have a ball shape, but the present disclosure is not limited thereto. For example, the core body 131 may have a spherical, polyhedral, or pillar shape (see the example embodiment of FIG. 5).

A width d2 of the through-hole 131H may be within a range of about 10% to about 50% of a width dl of the corresponding core body 131. The width dl of the core body 131 may be about 500 μm or less, for example, about 100 μm to about 500 μm, about 100 μm to about 400 μm, about 100 μm to about 300 μm, or the like, but the present disclosure is not limited thereto. Sizes of the core body 131 and the through-hole 131H may be determined in consideration of filling properties of a conductive material, a pitch between adjacent bumps, or the like.

In some example embodiments, the core body 131 may be positioned to be adjacent to the corresponding lower pad 112P1. For example, a distance in the Z direction between lower surfaces of the lower pads 112P1 corresponding to the core balls 130A and the core body 131 (as indicated by gap g1) may be less than a distance in the Z direction between a lowermost end of the conductive material layer 132 and the core body 131 (as indicated by gap g2).

At least some core balls 130A may include a first core ball 130Aa and a second core ball 130Ab that are adjacent to each other. When a distance DS1 between the center of the first core ball 130Aa and the center of the second core ball 130Ab is about 500 μm to about 600 μm, a separation distance ds1 between the first core ball 130Aa and the second core ball 130Ab may be about 550 μm or more, for example, about 550 μm to about 650 μm, about 550 μm to about 600 μm, or the like, but the present disclosure is not limited thereto.

Referring to FIG. 3, the core balls 130A and the conductive bumps 130B may be respectively disposed in the openings 114H of the protective layer 114. The protective layer 114 may include first openings 114H1 in which the core balls 130A are disposed, and second openings 114H2 in which the conductive bumps 130B are disposed. A width W1 of each of the first openings 114H1 and a width W2 of each of the second openings 114H2 may be substantially the same. Here, “the same” may be based on a concept including process errors of several μm to several tens of μm, and may mean not being intentionally designed to be different from each other.

The core balls 130A may have a relatively small vertical height or thickness, as compared to the conductive bumps 130B. For example, a height h1 in the Z direction of each of the core balls 130A relative to a lower (or upper) surface of the lower pads 112P1 may be less than a height h2 in the Z direction of each of the conductive bumps 130B relative to the lower (or upper) surface of the lower pads 112P1 (e.g., a thickness of each of the core balls 130A in the Z direction may be less than a thickness of each of the conductive bumps 130B in the Z direction). When a distance DS2 between the centers of core balls 130A and conductive bumps 130B that are adjacent to each other is about 500 μm to about 600 μm, a separation distance ds2 between the core balls 130AA and the conductive bumps 130B may be within a range of about 500 μm or more, for example, about 500 μm to about 600 μm, about 500 μm to about 550 μm, or the like, but the present disclosure is not limited thereto.

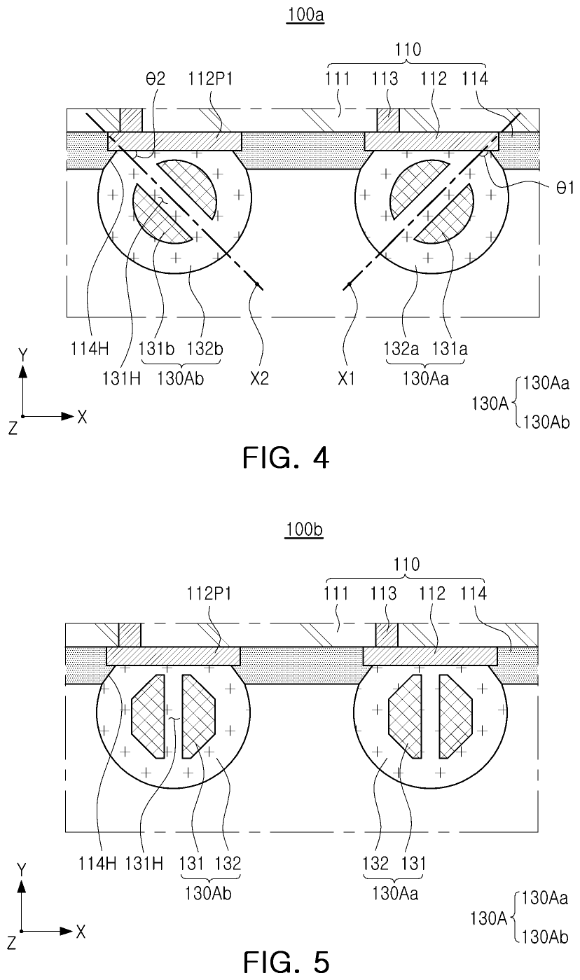

FIG. 4 is a partially enlarged view of a semiconductor package 100a according to an example embodiment.

Referring to FIG. 4, in an example embodiment, at least some core balls 130A may have features the same as or similar to those described with reference to FIGS. 1A to 3, except for an arrangement direction of a through-hole 131H. A first core ball 130Aa may include a first core body 131a having a first through-hole, and a first conductive material layer 132a covering or surrounding the first core body 131a. A second core ball 130Ab may include a second core body 131b having a second through-hole, and a second conductive material layer 132b covering or surrounding the second core body 131b. A first vertical axis (X1) of the first through-hole may have a first angle θ1 with respect to a lower surface of one corresponding lower pad, among lower pads 112P1, and a second vertical axis X2 of the second through-hole may have a second angle θ2 respect to with a lower surface of one corresponding lower pad, among the lower pads 112P1. The first angle θ1 and the second angle θ2 may be in a range of 0 degrees to 180 degrees. The first angle θ1 and the second angle θ2 may be defined as an angle between a lower surface of a lower pad 112P1 and the vertical axes (X1 and X2). In addition, “0 degrees” and “180 degrees” may mean that the vertical axes (X1 and X2) of the core bodies 131a and 131b may be substantially parallel to lower surfaces of the lower pads 112P1. In some example embodiments, the first angle θ1 and the second angle θ2 may be different from each other. In some example embodiments, the first core body 131a and the second core body 131b may be arranged such that the first angle θ1 and the second angle θ2 are the same.

FIG. 5 is a partially enlarged view of a semiconductor package 100b according to an example embodiment.

Referring to FIG. 5, in an example embodiment, at least some core balls 130A may have features the same as or similar to those described with reference to FIGS. 1A to 4, except for a shape of a core body 131. The shape of the core body 131 in which a through-hole 131H is formed is not particularly limited. For example, the core body 131 may have a polyhedral shape such as a tetrahedron, hexahedron, octahedron, dodecahedron, or icosahedron, a pillar shape such as a cylinder or prism, or a pyramid shape. In some embodiments, a first core ball 130Aa and a second core ball 130Ab may include core bodies 131 having different shapes.

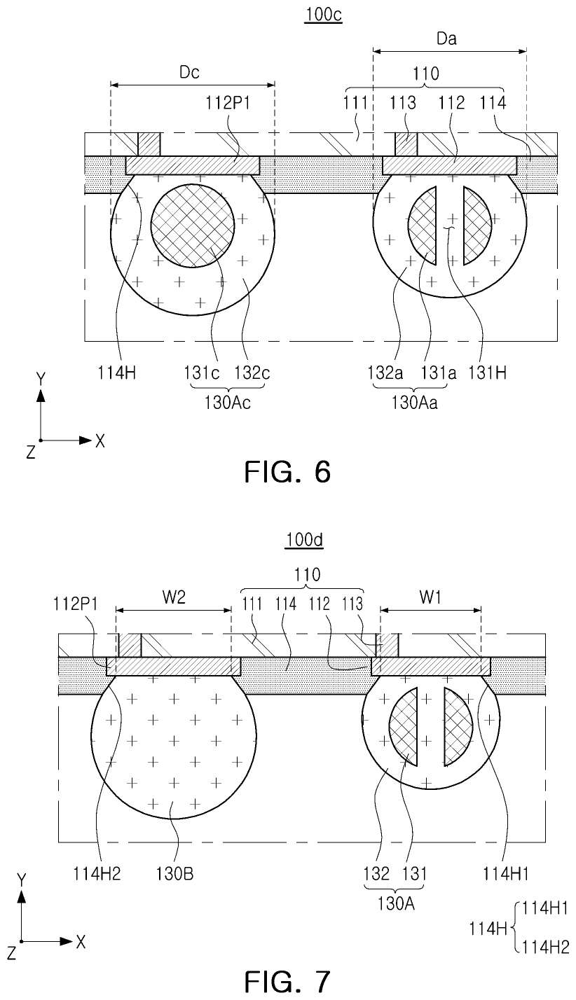

FIG. 6 is a partially enlarged view of a semiconductor package 100c according to an example embodiment.

Referring to FIG. 6, in an example embodiment, at least some core balls 130A may have features the same as or similar to those described with reference to FIGS. 1A to 5, except that a core body 131c having no through-hole is included. The core balls 130A may include a first core ball 130Aa and a third core ball 130Ac. The first core ball 130Aa may include a first core body 131a having a first through-hole, and a first conductive material layer 132a covering or surrounding the first core body 131a. The third core ball 130Ac may include a third core body 131c, and a third conductive material layer 132c extending along an external surface of the third core body 131c. The third core body 131c may not include a through-hole through which the third conductive material layer 132c passes or extends into. When the first core body 131a and the third core body 131c have the same diameter, an external shell portion of the third conductive material layer 132c may be thicker than an external shell portion of the first conductive material layer 132a. Accordingly, a horizontal width Dc in the X direction of the third core ball 130Ac may be greater than a horizontal width Da in the X direction of each of the first core balls 130Aa.

FIG. 7 is a partially enlarged view of a semiconductor package 100d according to an example embodiment.

Referring to FIG. 7, in an example modification, the semiconductor package 100d may have features the same as or similar to those described with reference to FIGS. 1A to 6, except for a size of each of openings 114H of a protective layer 114. The protective layer 114 may include first openings 114H1 in which the core balls 130A are disposed, and second openings 114H2 in which conductive bumps 130B are disposed. The core balls 130A may have a relatively small size (for example, a width, a height, a volume, or the like), as compared to the conductive bumps 130B. Accordingly, a width W1 in the X direction of each of the first openings 114H1 in which the core balls 130A are disposed may be less than a width W2 in the X direction of each of the second openings 114H2 in which the conductive bumps 130B are disposed.

FIG. 8A is a cross-sectional view of a semiconductor package 100B according to an example embodiment, FIG. 8B is a plan view of the semiconductor package in FIG. 8A, and FIG. 8C is a cross-sectional view of a chip structure 120′ according to an example embodiment.

Referring to FIGS. 8A and 8B, the semiconductor package 100B according to an example embodiment may have features the same as or similar to those described with reference to. FIGS. 1A to 7, except that a plurality of chip structures 120a and 120b (or “semiconductor chips”) are disposed on a substrate 110. In some example embodiments, the plurality of chip structures 120a and 120b may be provided as a single chip package structure, which will be described below with reference to FIG. 8C.

The semiconductor package 100B may include a first chip structure 120a and at least one second chip structure 120b. The first chip structure 120a and the second chip structure 120b may be electrically connected to each other through an interconnection layer 112 of the substrate 110.

The first chip structure 120a and the second chip structure 120b may include different types of semiconductor chips. For example, the first chip structure 120a may include a logic chip such as a CPU, a GPU, an FPGA, a digital signal processor, a cryptographic processor, a microprocessor, a microcontroller, an analog-digital converter, or an ASIC, and the second chip structure 120b may include a memory chip such as DRAM, SRAM, PRAM, ReRAM, FeRAM, MRAM, or flash memory. In some example embodiments, the second chip structure 120b may be provided as a high-performance memory device such as a high-bandwidth memory (HBM) or a hybrid memory cube (HMC). In some example embodiments, the first chip structure 120a and the second chip structure 120b may include the same type of semiconductor chip. For example, both the first chip structure 120a and the second chip structure 120b may include a logic chip or a memory chip.

Referring to FIG. 8C, a chip package structure 120′ according to an example embodiment may include a first chip structure 120a, at least one second chip structure 120b, and an interposer substrate 200.

The first chip structure 120a may include a logic chip such as a CPU, a GPU, a FPGA, a digital signal processor, a cryptographic processor, a microprocessor, a microcontroller, an analog-to-digital converter, an ASIC, or the like.

The at least one second chip structure 120b may include a plurality of semiconductor chips CD that are vertically stacked. The plurality of semiconductor chips CD may be electrically connected to each other through-vias TSV. An adhesive film layer DF, which at least partially surround metal bumps MB, may be disposed between the plurality of semiconductor chips CD. The adhesive film layer DF may include a non-conductive film NCF. The plurality of semiconductor chips CD may include a memory chip such as DRAM, SRAM, PRAM, ReRAM, FeRAM, MRAM, or flash memory. In some example embodiments, the second chip structure 120b may further include a buffer chip (not illustrated) for the plurality of semiconductor chips CD.

The interposer substrate 200 may include a semiconductor substrate 201, an upper circuit layer 210, a lower circuit layer 220, and through-vias 230. The interposer substrate 200 may include a lower terminal 200P1 and an upper terminal 200P2. The lower terminal 200P1 and the upper terminal 200P2 may include, for example, at least one metal material, among aluminum (Al), copper (Cu), nickel (Ni), tungsten (W), platinum (Pt), and gold (Au), but the present disclosure is not limited thereto.

The semiconductor substrate 201 may include a semiconductor element such as silicon or germanium, or a compound semiconductor such as silicon carbide (SiC), gallium arsenide (GaAs), indium arsenide (InAs), or indium phosphide (InP).

The upper circuit layer 210 may be disposed on an upper portion of the semiconductor substrate 201, and may include an interlayer insulating layer 211 and an upper connection interconnection 212. The interlayer insulating layer 211 may include silicon oxide or silicon nitride. The upper connection interconnection 212 may connect the first chip structure 120a and the second chip structure 120b to each other, or may connect the first chip structure 120a and the second chip structure 120b to the through-vias 230.

The lower circuit layer 220 may be disposed on a lower portion of the semiconductor substrate 201, and may include an interlayer insulating layer 221 and a lower connection interconnection 222. The interlayer insulating layer 221 and the lower connection interconnection 222 of the lower circuit layer 220 may include materials similar to those of the interlayer insulating layer 211 and the upper connection interconnection 212 of the upper circuit layer 210 described above.

The through-vias 230 may be through-silicon vias passing through or extending into the semiconductor substrate 201 in a vertical direction D3. The through-vias 230 may provide an electrical path connecting a lower terminal 200P1 and upper terminals 200P2 to each other. The through-via 230 may include a conductive plug and a barrier film surrounding the conductive plug. The conductive plug may include a metal material, for example, tungsten (W), titanium (Ti), aluminum (Al), or copper (Cu). The conductive plug may be formed using a plating process, a PVD process, or a CVD process. The barrier film may include an insulating barrier film and/or a conductive barrier film. The insulating barrier film may be formed of an oxide film, a nitride film, a carbonization film, a polymer, or combinations thereof. The conductive barrier film may include, for example, a metal compound such as tungsten nitride (WN), titanium nitride (TiN), or tantalum nitride (TaN). The barrier film may be formed using a PVD process or a CVD process.

In addition, a molded layer 124, encapsulating at least a portion of each of the first chip structure 120a and the second chip structure 120b, may be disposed on the interposer substrate 200. The molded layer 124 may include, for example, an epoxy molding compound (EMC), but the present disclosure is not limited thereto.

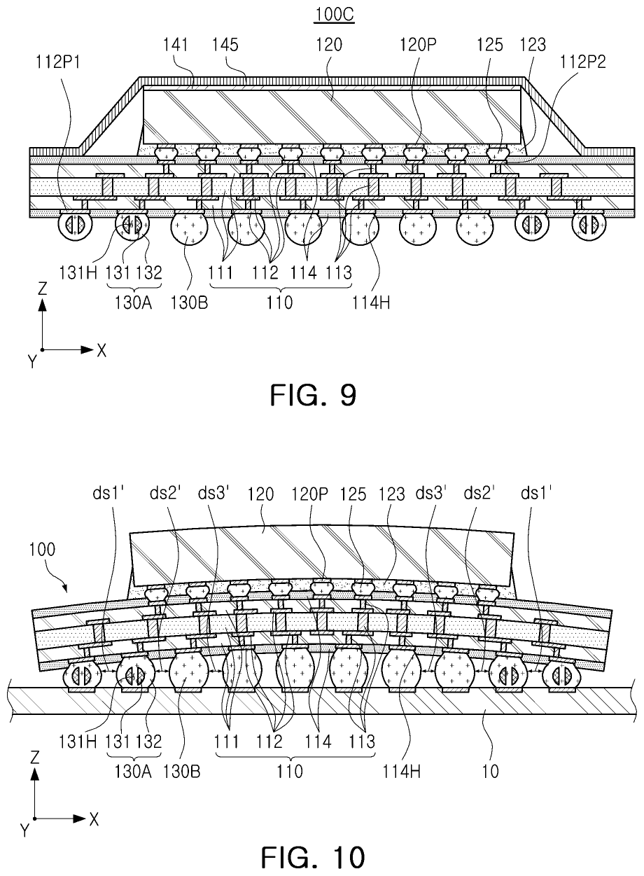

FIG. 9 is a cross-sectional view of a semiconductor package 100C according to an example embodiment.

Referring to FIG. 9, the semiconductor package 100C according to an example embodiment may have features the same as or similar to those described with reference to FIGS. 1A to 8C, except that a heat sink 145 on at least one chip structure 120 is further included. The heat sink 145 may control warpage of the semiconductor package 100C, and may externally dissipate heat generated from the chip structure 120. The heat sink 145 may include a material having excellent thermal conductivity, for example, aluminum (Al), gold (Au), silver (Ag), copper (Cu), iron (Fe), graphite, graphene, or the like. The heat sink 145 may have a plate shape, but the present disclosure is not limited thereto. The heat sink 145 may be in contact with the at least one chip structure 120 by an insulating thermally conductive layer 141. The insulating thermally conductive layer 141 may include a thermal interface material (TIM), for example a thermally conductive adhesive tape, thermally conductive grease, or a thermally conductive adhesive.

FIG. 10 is a diagram of a use state of a semiconductor package 100 according to an example embodiment.

Referring to FIG. 10, the semiconductor package 100 according to an example embodiment may be attached to an external device 10. The external device 10 may include a module board or a main board on which various electronic devices are mounted to drive electronic products. The semiconductor package 100 may be connected to the external device 10 through core balls 130A and conductive bumps 130B. The semiconductor package 100 may have warpage accumulated during a process in which the semiconductor package 100 is manufactured and assembled into the external device 10. For example, the semiconductor package 100 may have a convexly curved shape such that opposite ends thereof downwardly move (i.e., towards the external device 10 in the Z direction). Crying (or downward) warpage of the semiconductor package 100 may narrow distances ds1′ and ds2′ between solder bumps in the X direction disposed on the opposite ends, and may cause a short circuit. However, according to an example embodiment, the core balls 130A, disposed on the opposite ends of the semiconductor package 100, may include a core body 131 having a through-hole 131H, and thus may have a horizontal width relatively less than that of each of the conductive bumps 130B, thereby maintaining not only a distance ds3′ between the conductive bumps 130B disposed at the center of a substrate 110, but also a distance ds′ between core balls 130A disposed on an edge of the substrate 110 and a distance ds2′ between a core ball 130A and a conductive bump 130B, and preventing or inhibiting a short circuit between bumps.

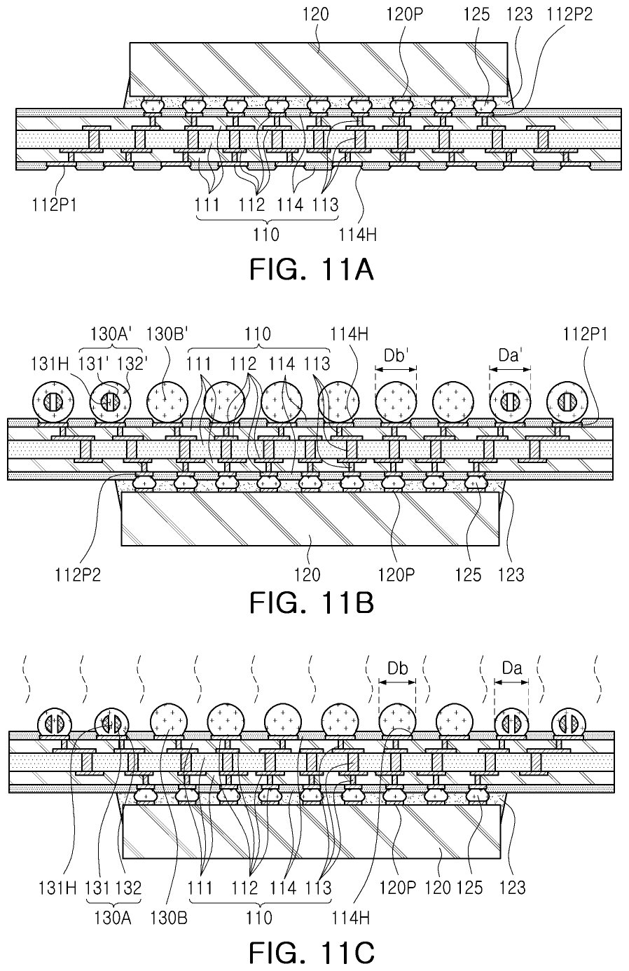

FIGS. 11A to 11C are diagrams of a process of manufacturing a semiconductor package according to an example embodiment.

Referring to FIG. 11A, at least one chip structure 120 may be mounted on a substrate 110. The substrate 110 may include an insulating layer 111, an interconnection layer 112, an interconnection vias 113, and a protective layer 114. The protective layer 114 may have openings, exposing a lower pad 112P1 and an upper pad 112P2. The chip structure 120 may be electrically connected to the upper pad 112P2 of the substrate 110 through connection bumps 125. The connection bumps 125 may be supported and fixed by an underfill layer 123.

Referring to FIG. 11B, first preliminary bumps 130A′ and second preliminary bumps 130B′ may be attached to lower pads 112P1 of the substrate 110. Each of the first preliminary bumps 130A′ may include a core 131′ and a solder layer 132′. The core 131′ may have an empty through-hole 131H. The solder layer 132′ may extend only along an external surface of the core 131′, and may not fill or be in the through-hole 131H. The second preliminary bumps 130B′ may include solder balls. A horizontal width Da′ of each of the first preliminary bumps 130A′ and a horizontal width Db′ of each of the second preliminary bumps 130B′ may be substantially the same, but the present disclosure is not limited thereto.

Referring to FIG. 11C, core balls 130A and conductive bumps 130B may be formed. The core balls 130A and the conductive bumps 130B may be formed by applying a high-temperature heat source to the first preliminary bumps 130A′ and the second preliminary bumps 130B′. The solder layer 132′, which covers or is on the external surface of the core 131′, may be reflowed to fill or be in the through-hole 131H. As compared to the solder layer 132′, which covers or is on the external surface of the core 131′, a volume of a conductive material layer 132, which covers or is on the external surface of the core body 131, may be reduced, such that a horizontal width Da of each of the core balls 130A may be less than a horizontal width Db of each of the conductive bumps 130B.

According to example embodiments of the present disclosure, core balls having a through-hole may be used, such that a semiconductor package may have improved reliability.

While example embodiments have been shown and described above, it will be apparent to those skilled in the art that modifications and variations could be made without departing from the scope of the present disclosure as defined by the appended claims.

What is claimed is:

1. A semiconductor package comprising:
a substrate that comprises upper pads, lower pads, and an interconnection layer electrically connecting respective ones of the upper pads and respective ones of the lower pads to each other;
at least one chip structure on a first surface of the substrate, wherein each of the at least one chip structure comprises connection pads;
connection bumps electrically connecting respective ones of the connection pads to the respective ones of the upper pads of the substrate;
an underfill layer that at least partially surrounds the connection bumps and is between the first surface of the substrate and the at least one chip structure; and
core balls and conductive bumps on a second surface of the substrate that is opposite to the first surface of the substrate,
wherein respective ones of the core balls and respective ones of the conductive bumps are electrically connected to the respective ones of the lower pads,
wherein each of the core balls comprises a core body and a conductive material layer that at least partially surrounds and extends into the core body, and
wherein a width of each of the core balls in a first direction that is parallel to the second surface of the substrate is less than a width of each of the conductive bumps in the first direction.

2. The semiconductor package of claim 1, wherein, in a plan view, the core balls are on a corner region of the substrate.

3. The semiconductor package of claim 2, wherein the corner region is adjacent to edges of the substrate that intersect each other.

4. The semiconductor package of claim 1, wherein:
the core body comprises copper (Cu), and
the conductive material layer and the conductive bumps comprise tin or an alloy of tin.

5. The semiconductor package of claim 1, wherein:
the substrate further comprises a protective layer that defines openings that expose at least a portion of each of the lower pads, and
the core balls and the conductive bumps are respectively in the openings.

6. The semiconductor package of claim 5, wherein:
the openings comprise first openings and second openings,
the core balls are in the first openings,
the conductive bumps are in the second openings, and
a width of each of the first openings in the first direction is different from a width of each of the second openings.

7. The semiconductor package of claim 1, wherein the core body has a spherical shape, a polyhedral shape, or a pillar shape.

8. The semiconductor package of claim 1, wherein a thickness of each of the core balls in a second direction that is perpendicular to the second surface of the substrate is less than a thickness of each of the conductive bumps in the second direction.

9. The semiconductor package of claim 1, further comprising:
a heat sink on the at least one chip structure, and
an insulating thermally conductive layer between the heat sink and the at least one chip structure.

10. A semiconductor package comprising:
a substrate that comprises lower pads and an interconnection layer electrically connected to the lower pads;
at least one chip structure that is on the substrate and is electrically connected to the interconnection layer; and
core balls on respective ones of the lower pads of the substrate,
wherein the core balls are electrically connected to the at least one chip structure through the interconnection layer,
wherein each of at least one core ball of the core balls comprises a core body and a conductive material layer that at least partially surrounds the core body,
wherein the core body comprises an external surface and an internal surface that define a through-hole extending from a first side of the external surface to a second side of the external surface, and
wherein the conductive material layer extends along the external surface and the internal surface of the core body.

11. The semiconductor package of claim 10, wherein a width of the through-hole of a first core ball of the at least one core ball in a direction that is parallel to a lower surface of the substrate is within a range of 10% to 50% of a width of the core body of the first core ball in the direction.

12. The semiconductor package of claim 10, wherein a distance between a lower surface of a first lower pad of the lower pads and the core body of a first core ball of the at least one core ball in a direction that is perpendicular to a lower surface of the substrate is less than a distance between a lowermost end of the conductive material layer of the first core ball and the core body of the first core ball in the direction.

13. The semiconductor package of claim 10, wherein the at least one core ball comprises:
a first core ball that is on a first lower pad of the respective ones of the lower pads, wherein the first core ball comprises a first core body that defines a first through-hole and a first conductive material layer that at least partially surrounds the first core body, and
a second core ball that is on a second lower pad of the respective ones of the lower pads, wherein the second core ball comprises a second core body that defines a second through-hole and a second conductive material layer that at least partially surrounds the second core body,
a first vertical axis of the first through-hole has a first angle with respect to a lower surface of the first lower pad, and
a second vertical axis of the second through-hole has a second angle with respect to a lower surface of the second lower pad.

14. The semiconductor package of claim 13, wherein the first angle and the second angle are different from each other.

15. The semiconductor package of claim 10, wherein:
the core balls further comprise a first core ball that comprises a first core body and a first conductive material layer extending along an external surface of the first core body, and
a width of the first core ball in a direction that is parallel to a lower surface of the substrate is greater than a width of each of the at least one core ball in the direction.

16. A semiconductor package comprising:
a substrate that comprises lower pads and an interconnection layer electrically connected to the lower pads;
at least one chip structure that is on the substrate and is electrically connected to the interconnection layer; and
a plurality of external connection bumps respectively on the lower pads,
wherein the plurality of external connection bumps comprise core balls and conductive bumps,
wherein the core balls comprise a core body and a conductive material layer that at least partially surrounds a surface of the core body,
wherein a first core ball of the core balls and a second core ball of the core balls are spaced apart from each other by a first distance in a direction that is parallel to a lower surface of the substrate,
wherein the first core ball and a first conductive bump of the conductive bumps are spaced apart from each other by a second distance in the direction, and
wherein the second distance is less than the first distance.

17. The semiconductor package of claim 16, wherein the first conductive bump and a second conductive bump of the conductive bumps are spaced apart from each other by a third distance in the direction, and wherein the third distance is less than the second distance.

18. The semiconductor package of claim 16, wherein:
the core body comprises a first metal, and
each of the conductive material layer and the conductive bumps comprise a second metal having a melting point lower than a melting point of the first metal.

19. The semiconductor package of claim 16, wherein the conductive material layer extends into the core body.

20. The semiconductor package of claim 16, wherein the core balls are on at least one of the lower pads that are adjacent to an edge of the substrate.
